(19) United States
(12) Patent Application Publication
(10) Pub. No.: US 2025/0138262 A1
(43) Pub. Date: May 1, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Meng-Jie LEE, Taichung City (TW); Nai-Hao KAO, Taichung City (TW)

(73) Assignee: SILICONWARE PRECISION INDUSTRIES CO., LTD., Taichung City (TW)

(21) Appl. No.: 18/654,049

(22) Filed: May 3, 2024

(30) Foreign Application Priority Data
Oct. 30, 2023 (TW) 112141567

(51) Int. Cl. G02B 6/42

(52) U.S. Cl. CPC G02B 6/4259; G02B 6/4269; G02B 6/4283

(57) ABSTRACT

An electronic package and a manufacturing method thereof are provided, in which at least one first electronic element, at least one second electronic element and an optical engine module are all disposed or heterogeneously integrated on a first circuit structure and are electrically connected to the first circuit structure. Furthermore, the first circuit structure is disposed on a carrier structure, so that the first circuit structure and the first electronic element, the second electronic element and the optical engine module on the first circuit structure are carried by the carrier structure, and the first electronic element, the second electronic element and the optical engine module are all electrically connected to the carrier structure via the first circuit structure. Therefore, the electronic package can improve data transmission performance, reduce insertion loss/power loss, or reduce the warpage problem.

### BACKGROUND

### 1. Technical Field

The present disclosure relates to an electronic packaging technology, and more particularly, to an electronic package that can be heterogeneously integrated with a plurality of electronic elements and an optical engine module and a manufacturing method thereof.

### 2. Description of Related Art

In response to the huge demand for data transmission, Co-Package Optic (CPO) has become an inevitable development trend. Meanwhile, the general silicon photonics structure is to design with the switch die and the optical engine (OE) module side by side, so that the switch die and the optical engine module are separately disposed on the left and right sides of the upper surface of the package substrate.

FIG. 1 is a schematic cross-sectional view of a semiconductor package 1 of conventional technology. As shown in FIG. 1, an optical engine module 11 of the semiconductor package 1 mainly comprises a photonic integrated circuit (PIC) 12 and an electronic integrated circuit (EIC) chip 13, and a switch die 10 and the optical engine module 11 are directly disposed on the left and right sides of an upper surface of a package substrate 14 in a side by side manner, and a plurality of solder balls 15 are disposed on a lower surface of the package substrate 14.

However, the semiconductor package 1 of conventional technology can merely be provided with the switch die 10 and the optical engine module 11 but cannot be heterogeneously integrated with more electronic elements, so it is difficult to improve the data transmission performance of the semiconductor package 1. Furthermore, the switch die 10 and the optical engine module 11 of the semiconductor package 1 of conventional technology are directly adjacent to each other and disposed on the left and right sides of the upper surface of the package substrate 14, thus causing the package substrate 14 difficult to control warpage and other problems. In addition, a spacing A between the switch die 10 and the optical engine module 11 of the semiconductor package 1 is too large, so it is easy to cause large insertion loss and power loss under high-speed operation.

Therefore, there is a need for a solution that addresses the aforementioned shortcomings in the prior art.

### SUMMARY

In view of the aforementioned shortcomings of the prior art, the present disclosure provides an electronic package, which comprises: a first circuit structure; at least one first electronic element, at least one second electronic element and an optical engine module disposed on or heterogeneously integrated with the first circuit structure, wherein the first electronic element, the second electronic element and the optical engine module are electrically connected to the first circuit structure; and a carrier structure carrying the first circuit structure and the first electronic element, the second electronic element and the optical engine module on the first circuit structure, wherein the first electronic element, the second electronic element and the optical engine module are electrically connected to the carrier structure via the first circuit structure.

The present disclosure also provides a method of manufacturing an electronic package, the method comprises: disposing or heterogeneously integrating at least one first electronic element, at least one second electronic element and an optical engine module on a first circuit structure, wherein the first electronic element, the second electronic element and the optical engine module are electrically connected to the first circuit structure; and disposing the first circuit structure on a carrier structure, wherein the first circuit structure and the first electronic element, the second electronic element and the optical engine module on the first circuit structure are carried by the carrier structure, and the first electronic element, the second electronic element and the optical engine module are electrically connected to the carrier structure via the first circuit structure.

In the aforementioned electronic package and method, the first circuit structure comprises at least one insulating layer and at least one redistribution layer formed on the insulating layer, and the first electronic element, the second electronic element and the optical engine module are electrically connected to the redistribution layer of the first circuit structure.

In the aforementioned electronic package and method, the first electronic element is a high bandwidth memory chip, the second electronic element is a switch die or an application specific integrated circuit, and the first electronic element, the second electronic element and the optical engine module are heterogeneously integrated on the first circuit structure.

In the aforementioned electronic package and method, the optical engine module has a photonic element, and the photonic element is connected to an optical fiber or a bus of an optical fiber cable.

In the aforementioned electronic package and method, the optical engine module has a photonic element, a control element and a second circuit structure, and the photonic element is electrically connected to the control element via the second circuit structure.

In the aforementioned electronic package and method, the optical engine module has a photonic element, a second circuit structure and a plurality of conductive pillars, and the photonic element is electrically connected to the first circuit structure via the second circuit structure and the plurality of conductive pillars in sequence.

In the aforementioned electronic package and method, the first electronic element, the second electronic element and the optical engine module are disposed on the first circuit structure in a misalignment arrangement.

In the aforementioned electronic package and method, the first electronic element and the optical engine module are disposed on the first circuit structure in a misalignment arrangement, and the first electronic element is adjacent to the optical engine module.

In the aforementioned electronic package and method, the second electronic element and the optical engine module are disposed on the first circuit structure in a misalignment arrangement, and a spacing between the second electronic element and the optical engine module is less than 1400 microns (μm).

In the aforementioned electronic package and method, the present disclosure further comprises disposing a stepped heat dissipating member having a first step portion and a second step portion on the carrier structure, wherein the second step portion of the stepped heat dissipating member is higher than the first step portion, the first step portion of the stepped heat dissipating member is in contact with the first electronic element and the second electronic element, and the second step portion of the stepped heat dissipating member is in contact with the optical engine module.

As can be understood from the above, in the electronic package and the manufacturing method thereof of the present disclosure, at least one first electronic element (such as a high bandwidth memory chip), at least one second electronic element (such as a switch die/application specific integrated circuit) and the optical engine module (including a photonic element and a control element) are all disposed or heterogeneously integrated on the first circuit structure, thereby greatly improving or doubling the data transmission performance of the electronic package, and also improving or increasing the electrical performance of the electronic package.

Meanwhile, in the present disclosure, the first electronic element, the second electronic element and the optical engine module are all disposed or heterogeneously integrated on the first circuit structure, so that the spacing between the first electronic element, the second electronic element and the optical engine module is reduced. Therefore, the electronic package can reduce insertion loss and power loss during high-speed operation, and can reduce warpage problems during production.

Furthermore, in the present disclosure, all or any two of the first electronic element, the second electronic element and the optical engine module are disposed on the first circuit structure in a misalignment arrangement, which facilitates shortening the spacing between the first electronic element, the second electronic element and the optical engine module to reduce insertion loss and power loss.

In addition, in the present disclosure, the first step portion and the second step portion of the stepped heat dissipating member are in contact with the first/second electronic element and the optical engine module respectively, so that heat generated from the first/second electronic element and the optical engine module can be effectively dissipated by the stepped heat dissipating member, and overheating of the first/second electronic element and the optical engine module can also be avoided to improve operating performance.

### BRIEF DESCRIPTION OF THE DRAWINGS

FIG. 1 is a schematic cross-sectional view of a semiconductor package of conventional technology.

FIG. 2A, FIG. 2B, FIG. 2C and FIG. 2D are schematic cross-sectional views illustrating a method of manufacturing an electronic package of the present disclosure.

FIG. 2B′ is a schematic top view of FIG. 2B.

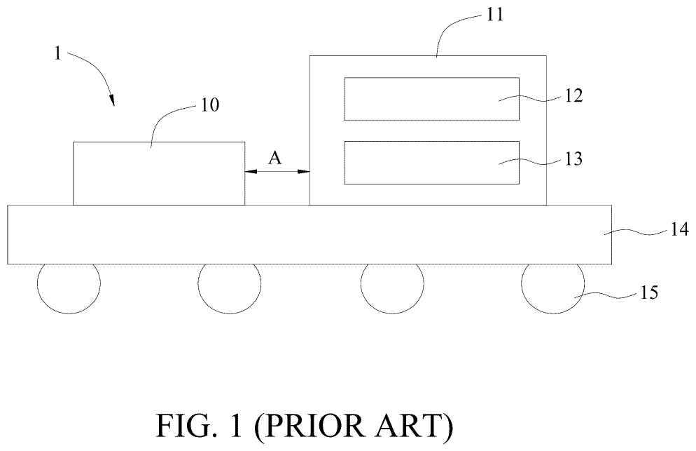

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “below,” “a,” “one,” “two,” “first,” “second,” “third,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

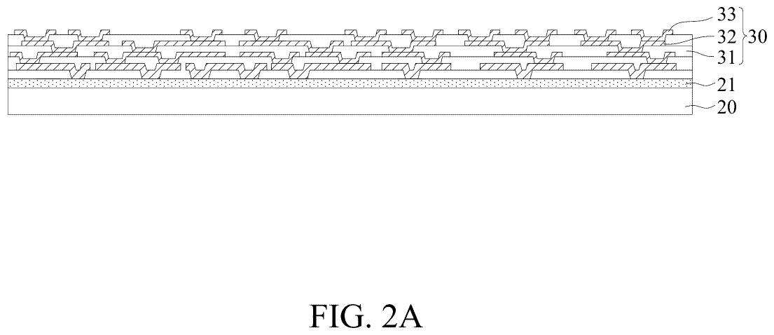

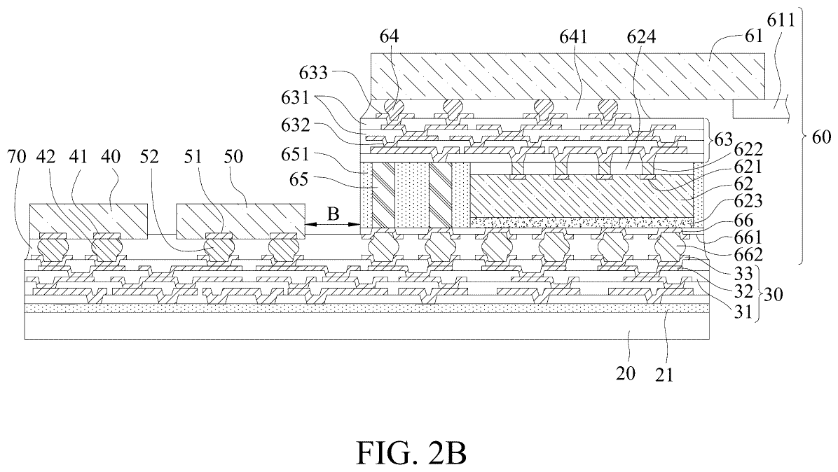

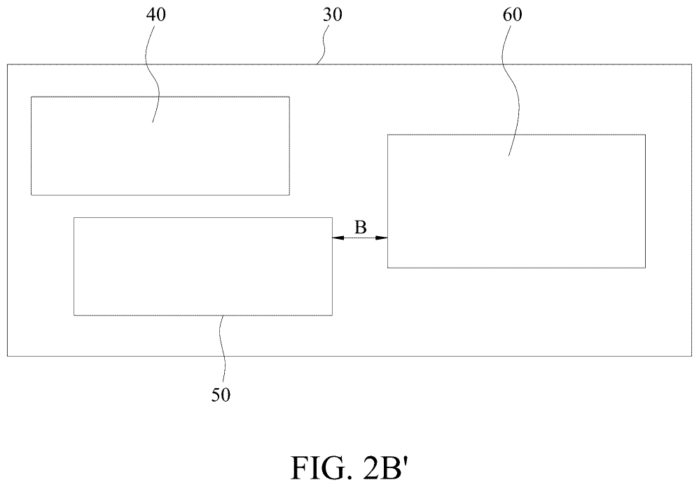

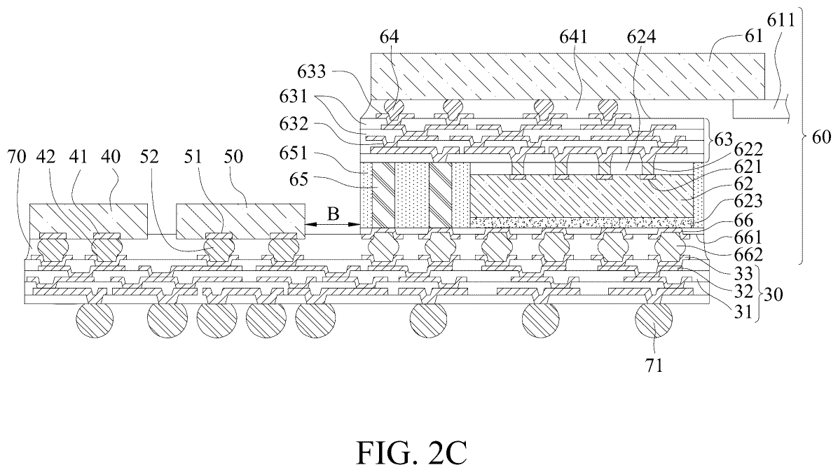

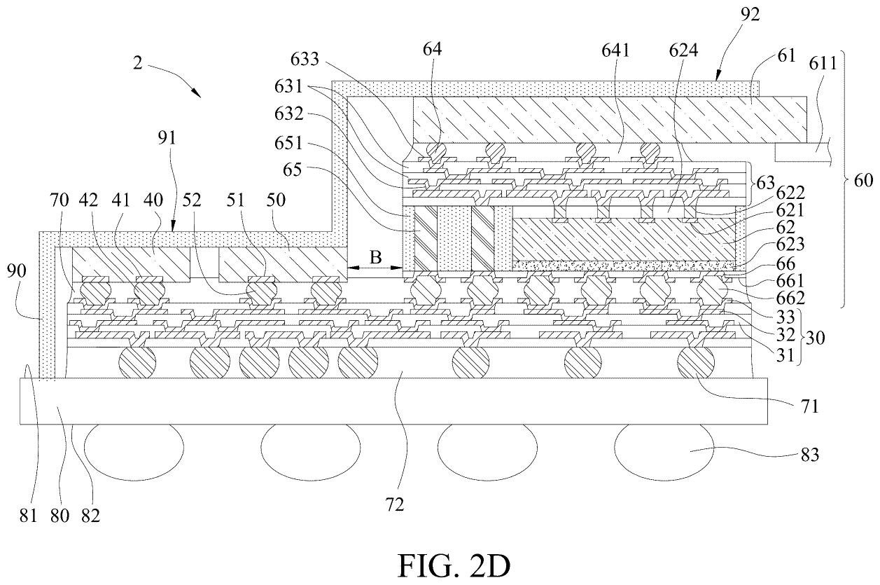

FIG. 2A, FIG. 2B, FIG. 2C and FIG. 2D are schematic cross-sectional views illustrating a method of manufacturing an electronic package 2 of the present disclosure, and FIG. 2B′ is a schematic top view of FIG. 2B. Meanwhile, “at least one” in the present disclosure represents one or more (such as one, two, or three), and “plurality” represents two or more (such as two, three, four, ten, or more than ten).

As shown in FIG. 2A, a first circuit structure 30 is first formed on a carrier 20.

In one embodiment, the carrier 20 can be a board body made of semiconductor material (such as silicon or glass), and a release layer 21 is formed on the carrier 20 by, for example, coating, so that the first circuit structure 30 is disposed on the release layer 21 of the carrier 20.

In one embodiment, the first circuit structure 30 comprises a plurality of insulating layers 31 and a plurality of redistribution layers (RDLs) 32 formed on the plurality of insulating layers 31, and a portion of the outermost layer (such as the top layer) of the redistribution layer 32 is exposed to serve as an electrical contact pad 33. Alternatively, the first circuit structure 30 may merely comprise a single insulating layer 31 and a single redistribution layer 32 formed on the single insulating layer 31. That is, the first circuit structure 30 may comprise at least one (such as a plurality of) insulating layer 31 and at least one (such as a plurality of) redistribution layer 32 formed on the insulating layer 31, and the redistribution layer 32 of the first circuit structure 30 may be, for example, a fan-out type redistribution layer.

In one embodiment, a material of the insulating layer 31 is dielectric material such as polybenzoxazole (PBO), polyimide (PI), prepreg (PP), etc., or solder-resist material such as solder mask (e.g., green solder mask), graphite (e.g., ink), etc., and a material of the redistribution layer 32 is copper, etc., but not limited to the above.

As shown in FIG. 2B, at least one (such as a plurality of) first electronic element 40, at least one (such as a plurality of) second electronic element 50 and an optical engine module 60 are all disposed or heterogeneously integrated on the first circuit structure 30, and the first electronic element 40, the second electronic element 50 and the optical engine module 60 are electrically connected to the redistribution layer 32 of the first circuit structure 30.

In one embodiment, the first electronic element 40 may be, for example, a first chip or a high bandwidth memory (HBM) chip, etc., and the second electronic element 50 may be, for example, a second chip, a switch die, or an application specific integrated circuit (ASIC), etc., but not limited to the above. In other embodiments, the first electronic element 40 and the second electronic element 50 can also be other functional chips.

In one embodiment, the first electronic element 40 can have a plurality of electrode pads 41, and the second electronic element 50 can have a plurality of electrode pads 51. Therefore, the plurality of electrode pads 41 of the first electronic element 40 can be electrically connected to the redistribution layer 32 of the first circuit structure 30 by a plurality of conductors 42 in a flip-chip manner, and the plurality of electrode pads 51 of the second electronic element 50 are electrically connected to the redistribution layer 32 of the first circuit structure 30 by a plurality of conductors 52 in a flip-chip manner. Alternatively, the plurality of electrode pads 41 of the first electronic element 40 can be electrically connected to the redistribution layer 32 of the first circuit structure 30 by a plurality of wires (not shown) in a wire bonding manner, and the plurality of electrode pads 51 of the second electronic element 50 are electrically connected to the redistribution layer 32 of the first circuit structure 30 by a plurality of wires (not shown) in a wire bonding manner. There are many ways for the first electronic element 40 or the second electronic element 50 to be electrically connected to the redistribution layer 32 of the first circuit structure 30, but not limited to the above.

In one embodiment, the conductors 42 or the conductors 52 are conductive lines, spherical conductive members such as solder balls, cylindrical metal conductive members such as copper pillars, conductive bumps, solder bumps, etc., or stud-shaped conductive members made by a wire bonding machine, but not limited to the above.

In one embodiment, the optical engine module 60 may have a photonic element 61 (or photoelectric element), a control element 62 and a second circuit structure 63, so that the photonic element 61 is electrically connected to the control element 62 via the second circuit structure 63. For example, the photonic element 61 may be a photonic chip (PIC or optoelectronic chip), etc., and the control element 62 may be a control chip or an electronic integrated circuit (EIC) chip, etc.

In one embodiment, the photonic element 61 of the optical engine module 60 can be connected to an optical fiber 611 or a bus of the optical fiber cable, so that the photonic element 61 can quickly transmit optical signals via the optical fiber 611 or the bus of the optical fiber cable.

In one embodiment, the control element 62 of the optical engine module 60 may have a plurality of electrode pads 621, so that the plurality of electrode pads 621 of the control element 62 can be electrically connected to a redistribution layer 632 of the second circuit structure 63 by a plurality of conductors 622. For example, the conductors 622 may be conductive lines, spherical conductive members such as solder balls, cylindrical metal conductive members such as copper pillars, conductive bumps, solder bumps, etc., or stud-shaped conductive members made by a wire bonding machine, but not limited to the above.

In one embodiment, the control element 62 of the optical engine module 60 may have an active surface and an inactive surface opposing the active surface. The inactive surface of the control element 62 is bonded or adhered onto a wiring structure 66 by a bonding layer 623, and the plurality of electrode pads 621 on the active surface of the control element 62 are covered with a protective film 624 made of such as passivation material, and the plurality of conductors 622 are disposed in the protective film 624.

In one embodiment, the second circuit structure 63 of the optical engine module 60 comprises a plurality of insulating layers 631 and a plurality of the redistribution layers 632 formed on the plurality of insulating layers 631, the outermost layer (such as the top layer) of the insulating layer 631 can be used as a solder-resist layer, and a portion of the outermost layer (such as the top layer) of the redistribution layer 632 is exposed from the solder-resist layer to serve as an electrical contact pad 633. Alternatively, the second circuit structure 63 may merely comprise a single insulating layer 631 and a single redistribution layer 632. That is, the second circuit structure 63 may comprise at least one (such as a plurality of) insulating layer 631 and at least one (such as a plurality of) redistribution layer 632, and the redistribution layer 632 may be, for example, a fan-out type redistribution layer.

In one embodiment, a material of the insulating layer 631 is dielectric material such as polybenzoxazole (PBO), polyimide (PI), prepreg (PP), etc., or solder-resist material such as solder mask (e.g., green solder mask), graphite (e.g., ink), etc., and a material of the redistribution layer 632 is copper, but not limited to the above.

In one embodiment, the optical engine module 60 may have a plurality of conductive elements 64 and an underfill 641, so that the photonic element 61 is electrically connected to a plurality of the electrical contact pads 633 of the second circuit structure 63 via the plurality of conductive elements 64, and then the underfill 641 is formed between the photonic element 61 and the second circuit structure 63 to cover the plurality of conductive elements 64. For example, the conductive elements 64 may be copper pillars or solder balls.

In one embodiment, the optical engine module 60 may have a plurality of conductive pillars 65, an encapsulating layer 651, the wiring structure 66 and an insulating layer 661, so that the redistribution layer 632 of the second circuit structure 63 is electrically connected to the wiring structure 66 via the plurality of conductive pillars 65, and the plurality of conductive pillars 65 and the control element 62 are covered by the encapsulating layer 651. Meanwhile, the encapsulating layer 651 may have an upper surface and a lower surface opposing the upper surface, so that the lower surface of the encapsulating layer 651 is bonded onto the insulating layer 661, and the upper end surfaces of the plurality of conductive pillars 65 and the upper end surfaces of the plurality of conductors 622 are exposed from the upper surface of the encapsulating layer 651.

In one embodiment, a material of the conductive pillar 65 is copper metal material or solder material, etc., and the encapsulating layer 651 is made of insulating material, such as polyimide (PI), dry film, or encapsulant or molding compound such as epoxy resin, and a material of the insulating layer 661 is dielectric material such as polybenzoxazole (PBO), polyimide (PI), prepreg (PP), etc., or solder-resist material such as solder mask (e.g., green solder mask), graphite (e.g., ink), etc. For example, the encapsulating layer 651 may be formed on the insulating layer 661 in a manner of liquid compound, injection, lamination, or compression molding.

In one embodiment, the leveling process can be used to make the upper end surfaces of the conductors 622, the upper surface of the protective film 624, the upper end surfaces of the conductive pillars 65 and the upper surface of the encapsulating layer 651 flush or coplanar, so that the upper end surfaces of the conductors 622 and the upper end surfaces of the conductive pillars 65 are exposed from the upper surface of the protective film 624 and the upper surface of the encapsulating layer 651, respectively. For example, a portion of the material of each of the conductors 622, a portion of the material of the protective film 624, a portion of the material of each of the conductive pillars 65, and a portion of the material of the encapsulating layer 651 are removed by a leveling process (such as grinding). Also, the lower end surfaces of the conductive pillars 65 and the lower surface of the encapsulating layer 651 may also be flush or coplanar.

However, in other embodiments, the upper end surfaces of the conductors 622, the upper surface of the protective film 624, the upper end surfaces of the conductive pillars 65 and the upper surface of the encapsulating layer 651 may also be non-flush or non-coplanar, and the lower end surfaces of the conductive pillars 65 and the lower surface of the encapsulating layer 651 may also be non-flush or non-coplanar.

In one embodiment, the optical engine module 60 may have a plurality of conductive elements 662, so that the photonic element 61 is electrically connected to the redistribution layer 32 of the first circuit structure 30 via the plurality of conductive elements 64, the second circuit structure 63, the plurality of conductive pillars 65, the wiring structure 66 and the plurality of conductive elements 662 in sequence. For example, the conductive elements 662 may be copper pillars or solder balls.

Then, an underfill 70 is formed on the first circuit structure 30, between the first circuit structure 30 and the first electronic element 40, between the first circuit structure 30 and the second electronic element 50, and between the first circuit structure 30 and the optical engine module 60, such that the plurality of conductors 42, the plurality of conductors 52 and the plurality of conductive elements 662 of the optical engine module 60 are covered by the underfill 70.

As shown in FIG. 2B′, all or any two of the first electronic element 40, the second electronic element 50 and the optical engine module 60 are disposed on the first circuit structure 30 in a misalignment arrangement, and a spacing B between the second electronic element 50 and the optical engine module 60 is less than 1400 microns (μm) to reduce insertion loss and power loss.

In one embodiment, the first electronic element 40 (such as the first chip/high

bandwidth memory chip) and the second electronic element 50 (such as the second chip/switch die/application specific integrated circuit) are disposed on the first circuit structure 30 in a misalignment arrangement, and the first electronic element 40 is adjacent to the second electronic element 50. Alternatively, the first electronic element 40 and the optical engine module 60 are disposed on the first circuit structure 30 in a misalignment arrangement, and the first electronic element 40 is adjacent to the optical engine module 60. Alternatively, the second electronic element 50 and the optical engine module 60 are disposed on the first circuit structure 30 in a misalignment arrangement, and the second electronic element 50 is adjacent to the optical engine module 60. Thereby, in the present disclosure, the spacing between the first electronic element 40, the second electronic element 50 and the optical engine module 60 can be shorten to reduce insertion loss and power loss.

In other words, all or any two of the first electronic element 40, the second electronic element 50 and the optical engine module 60 can be disposed on the first circuit structure 30 in a misalignment arrangement to facilitate shortening the spacing between the first electronic element 40, the second electronic element 50 and the optical engine module 60 so as to reduce insertion loss and power loss. For example, the first electronic element 40, the second electronic element 50 and the optical engine module 60 are not arranged in a straight line, the first electronic element 40 is not arranged between the second electronic element 50 and the optical engine module 60, and the second electronic element 50 is also not arranged between the first electronic element 40 and the optical engine module 60.

As shown in FIG. 2C, the carrier 20 and the release layer 21 thereon shown in FIG. 2B are removed to expose the first circuit structure 30, and then a plurality of conductive elements 71 are bonded to the first circuit structure 30. For example, the conductive elements 71 may be copper pillars or solder balls.

As shown in FIG. 2D, the first circuit structure 30 can be disposed on a carrier structure 80, so that the first circuit structure 30 and the first electronic element 40, the second electronic element 50 and the optical engine module 60 on the first circuit structure 30 are carried by the carrier structure 80, and the first electronic element 40, the second electronic element 50 and the optical engine module 60 can all be electrically connected to the carrier structure 80 via the first circuit structure 30 and the plurality of conductive elements 71, so as to obtain the electronic package 2 of the present disclosure.

In one embodiment, the first electronic element 40 can be electrically connected to the carrier structure 80 via the plurality of conductors 42, the redistribution layer 32 of the first circuit structure 30 and the plurality of conductive elements 71 in sequence, the second electronic element 50 can be electrically connected to the carrier structure 80 via the plurality of conductors 52, the redistribution layer 32 of the first circuit structure 30 and the plurality of conductive elements 71 in sequence, and the optical engine module 60 can be electrically connected to the carrier structure 80 via the redistribution layer 32 of the first circuit structure 30 and the plurality of conductive elements 71 in sequence.

In one embodiment, the carrier structure 80 may be in the form of a substrate and have a first side 81 and a second side 82 opposing the first side 81, so that the first circuit structure 30 is disposed on the first side 81 of the carrier structure 80. For example, the carrier structure 80 is a package substrate with a core layer and a circuit structure, or a coreless circuit structure, the circuit structure comprises at least one insulating layer and at least one circuit layer bonded to the insulating layer, and the circuit layer can be a fan-out type redistribution layer (RDL). It should be understood that the carrier structure 80 can also be other board materials, such as a lead frame, a wafer, or other carrying board with metal routing, but not limited to the above.

In one embodiment, the second side 82 of the carrier structure 80 can be configured with a plurality of solder balls 83, so that the carrier structure 80 can be connected onto an electronic device (not shown) such as a circuit board via the plurality of solder balls 83.

Next, an underfill 72 is formed between the first circuit structure 30 (the insulating layer 31) and the first side 81 of the carrier structure 80, so that the plurality of conductive elements 71 are covered by the underfill 72.

Then, a stepped heat dissipating member 90 (a step-shaped heat sink) having a first step portion 91 and a second step portion 92 can be disposed on the first side 81 of the carrier structure 80, wherein the second step portion 92 of the stepped heat dissipating member 90 is higher than the first step portion 91, and the stepped heat dissipating member 90 can be in contact with the surfaces of the first electronic element 40, the second electronic element 50 and the optical engine module 60 (e.g., all or part of the upper surfaces of the first electronic element 40, the second electronic element 50 and the optical engine module 60).

In one embodiment, the first step portion 91 of the stepped heat dissipating member 90 can be in contact with the surfaces (such as the upper surface or the inactive surface) of the first electronic element 40 and the second electronic element 50, and the second step portion 92 of the stepped heat dissipating member 90 can be in contact with the surface (such as the upper surface) of the optical engine module 60 (the photonic element 61), so that the heat generated from the electronic package 2, the first electronic element 40, the second electronic element 50 and the optical engine module 60 can be effectively dissipated by the stepped heat dissipating member 90, and overheating of the electronic package 2, the first electronic element 40, the second electronic element 50 and the optical engine module 60 can also be avoided to improve operating performance.

In addition, in the embodiment of other manufacturing methods, the first circuit structure 30 can be disposed on the carrier structure 80 first, and then the first electronic element 40, the second electronic element 50 and the optical engine module 60 can all be disposed on the first circuit structure 30, so that the first circuit structure 30 and the first electronic element 40, the second electronic element 50 and the optical engine module 60 on the first circuit structure 30 are carried by the carrier structure 80, such that the first electronic element 40, the second electronic element 50 and the optical engine module 60 can all be electrically connected to the carrier structure 80 via the first circuit structure 30 and the plurality of conductive elements 71.

The present disclosure also provides an electronic package 2, which comprises: a first circuit structure 30; at least one first electronic element 40, at least one second electronic element 50 and an optical engine module 60 all disposed or heterogeneously integrated on the first circuit structure 30, wherein the first electronic element 40, the second electronic element 50 and the optical engine module 60 are electrically connected to the first circuit structure 30; and a carrier structure 80 carrying the first circuit structure 30 and the first electronic element 40, the second electronic element 50 and the optical engine module 60 on the first circuit structure 30, wherein the first electronic element 40, the second electronic element 50 and the optical engine module 60 are all electrically connected to the carrier structure 80 via the first circuit structure 30.

In one embodiment, the first circuit structure 30 comprises at least one insulating layer 31 and at least one redistribution layer 32 formed on the insulating layer 31, and the first electronic element 40, the second electronic element 50 and the optical engine module 60 are electrically connected to the redistribution layer 32 of the first circuit structure 30.

In one embodiment, the first electronic element 40 may be a high bandwidth memory chip, the second electronic element 50 may be a switch die or an application specific integrated circuit, and the first electronic element 40, the second electronic element 50 and the optical engine module 60 are all integrated on the first circuit structure 30.

In one embodiment, the optical engine module 60 has a photonic element 61, and the photonic element 61 is connected to an optical fiber 611 or a bus of an optical fiber cable.

In one embodiment, the optical engine module 60 has a photonic element 61, a control element 62 and a second circuit structure 63, and the photonic element 61 is electrically connected to the control element 62 via the second circuit structure 63.

In one embodiment, the optical engine module 60 has a photonic element 61, a second circuit structure 63 and a plurality of conductive pillars 65, and the photonic element 61 is electrically connected to the first circuit structure 30 via the second circuit structure 63 and the plurality of conductive pillars 65 in sequence.

In one embodiment, the first electronic element 40, the second electronic element 50 and the optical engine module 60 are all disposed on the first circuit structure 30 in a misalignment arrangement.

In one embodiment, the first electronic element 40 and the optical engine module 60 are disposed on the first circuit structure 30 in a misalignment arrangement, and the first electronic element 40 is adjacent to the optical engine module 60.

In one embodiment, the second electronic element 50 and the optical engine module 60 are disposed on the first circuit structure 30 in a misalignment arrangement, and a spacing B between the second electronic element 50 and the optical engine module 60 is less than 1400 microns (μm).

In one embodiment, the electronic package 2 further comprises a stepped heat dissipating member 90 having a first step portion 91 and a second step portion 92 and disposed on the carrier structure 80, wherein the second step portion 92 of the stepped heat dissipating member 90 is higher than the first step portion 91, the first step portion 91 of the stepped heat dissipating member 90 is in contact with the first electronic element 40 and the second electronic element 50, and the second step portion 92 of the stepped heat dissipating member 90 is in contact with the optical engine module 60.

In view of the above, the electronic package and the manufacturing method thereof of the present disclosure have at least the following features, advantages, or technical effects.
1. Since co-package optic (CPO) is the main technology for next-generation data centers and high-speed computing applications, the packaging type of integrating the first electronic element (such as a high bandwidth memory chip), the second electronic element (such as a switch die) and the optical engine module is a necessary trend. Therefore, the present disclosure makes good use of, for example, fan-out multi-chip-module (FO-MCM) technology to electrically connect the first circuit structure to the first electronic element (such as a high bandwidth memory chip), the second electronic element (such as a switch die) and the optical engine module to facilitate the use of flexible architecture and lower cost to meet various silicon optical terminal applications.
2. The present disclosure is based on, for example, a fan-out multi-chip-module (FO-MCM), and makes good use of a concept of integrating the first electronic element (such as a high bandwidth memory chip), the second electronic element (such as a switch die) and the optical engine module to a chip module, which facilitates the electronic package to significantly reduce insertion loss and power loss, and also has the advantage of meeting all silicon optical terminal applications.
3. In the present disclosure, at least one first electronic element (such as a high bandwidth memory chip), at least one second electronic element (such as a switch die/application specific integrated circuit) and the optical engine module (such as including a photonic element and a control element) are all disposed on the first circuit structure, so that the data transmission performance of the electronic package can be greatly improved or multiplied, and the electrical performance of the electronic package can also be improved or increased.
4. In the present disclosure, the first electronic element, the second electronic element and the optical engine module are all disposed on the first circuit structure, so that the spacing between the first electronic element, the second electronic element and the optical engine module is reduced. Therefore, the electronic package can reduce insertion loss and power loss during high-speed operation, and reduce warpage problems during production.
5. In the semiconductor package of conventional technology, the switch die and the optical engine module are directly disposed on the left and right sides of the package substrate in a side by side manner, so warpage controlling is difficult. By contrast, in the electronic package of the present disclosure, the first electronic element, the second electronic element and the optical engine module are all disposed on the first circuit structure, and the first circuit structure is further disposed on the carrier structure (such as the package substrate), which facilitates improving the problem of difficult warpage control in the conventional technology.
6. In the present disclosure, all or any two of the first electronic element, the second electronic element and the optical engine module are disposed on the first circuit structure in a misalignment arrangement, so as to facilitate shortening the spacing of the first electronic element, the second electronic element and the optical engine module to reduce insertion loss and power loss.
7. In the present disclosure, all or any two of the first electronic element, the second electronic element and the optical engine module are disposed on the first circuit structure in a misalignment arrangement, and the spacing between the second electronic element and the optical engine module can be less than 1400 microns (μm) to reduce insertion loss and power loss.
8. The photonic element of the optical engine module of the present disclosure can be connected to an optical fiber or the bus of an optical fiber cable, so that the photonic element can quickly transmit optical signals via the optical fiber or the bus of the optical fiber cable.
9. In the present disclosure, the first step portion and the second step portion of the stepped heat dissipating member are in contact with the first/second electronic element and the optical engine module respectively, so that heat generated from the first/second electronic element and the optical engine module can be effectively dissipated by the stepped heat dissipating member, and overheating of the first/second electronic element and the optical engine module can also be avoided to improve operating performance.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a first circuit structure;
a first electronic element, a second electronic element and an optical engine module disposed on the first circuit structure, wherein the first electronic element, the second electronic element and the optical engine module are electrically connected to the first circuit structure; and
a carrier structure carrying the first circuit structure and the first electronic element, the second electronic element and the optical engine module on the first circuit structure, wherein the first electronic element, the second electronic element and the optical engine module are electrically connected to the carrier structure via the first circuit structure.

2. The electronic package of claim 1, wherein the first circuit structure comprises an insulating layer and a redistribution layer formed on the insulating layer, and the first electronic element, the second electronic element and the optical engine module are electrically connected to the redistribution layer of the first circuit structure.

3. The electronic package of claim 1, wherein the first electronic element is a high bandwidth memory chip, the second electronic element is a switch die or an application specific integrated circuit, and the first electronic element, the second electronic element and the optical engine module are heterogeneously integrated on the first circuit structure.

4. The electronic package of claim 1, wherein the optical engine module has a photonic element, and the photonic element is connected to an optical fiber or a bus of an optical fiber cable.

5. The electronic package of claim 1, wherein the optical engine module has a photonic element, a control element and a second circuit structure, and the photonic element is electrically connected to the control element via the second circuit structure.

6. The electronic package of claim 1, wherein the optical engine module has a photonic element, a second circuit structure and a plurality of conductive pillars, and the photonic element is electrically connected to the first circuit structure via the second circuit structure and the plurality of conductive pillars in sequence.

7. The electronic package of claim 1, wherein the first electronic element, the second electronic element and the optical engine module are disposed on the first circuit structure in a misalignment arrangement.

8. The electronic package of claim 1, wherein the first electronic element and the optical engine module are disposed on the first circuit structure in a misalignment arrangement, and the first electronic element is adjacent to the optical engine module.

9. The electronic package of claim 1, wherein the second electronic element and the optical engine module are disposed on the first circuit structure in a misalignment arrangement, and a spacing between the second electronic element and the optical engine module is less than 1400 microns.

10. The electronic package of claim 1, further comprising a stepped heat dissipating member having a first step portion and a second step portion and disposed on the carrier structure, wherein the second step portion of the stepped heat dissipating member is higher than the first step portion, the first step portion of the stepped heat dissipating member is in contact with the first electronic element and the second electronic element, and the second step portion of the stepped heat dissipating member is in contact with the optical engine module.

11. A method of manufacturing an electronic package, comprising:
disposing a first electronic element, a second electronic element and an optical engine module on a first circuit structure, wherein the first electronic element, the second electronic element and the optical engine module are electrically connected to the first circuit structure; and
disposing the first circuit structure on a carrier structure, wherein the first circuit structure and the first electronic element, the second electronic element and the optical engine module on the first circuit structure are carried by the carrier structure, and the first electronic element, the second electronic element and the optical engine module are electrically connected to the carrier structure via the first circuit structure.

12. The method of claim 11, wherein the first circuit structure comprises an insulating layer and a redistribution layer formed on the insulating layer, and the first electronic element, the second electronic element and the optical engine module are electrically connected to the redistribution layer of the first circuit structure.

13. The method of claim 11, wherein the first electronic element is a high bandwidth memory chip, the second electronic element is a switch die or an application specific integrated circuit, and the first electronic element, the second electronic element and the optical engine module are heterogeneously integrated on the first circuit structure.

14. The method of claim 11, wherein the optical engine module has a photonic element, and the photonic element is connected to an optical fiber or a bus of an optical fiber cable.

15. The method of claim 11, wherein the optical engine module has a photonic element, a control element and a second circuit structure, and the photonic element is electrically connected to the control element via the second circuit structure.

16. The method of claim 11, wherein the optical engine module has a photonic element, a second circuit structure and a plurality of conductive pillars, and the photonic element is electrically connected to the first circuit structure via the second circuit structure and the plurality of conductive pillars in sequence.

17. The method of claim 11, wherein the first electronic element, the second electronic element and the optical engine module are disposed on the first circuit structure in a misalignment arrangement.

18. The method of claim 11, wherein the first electronic element and the optical engine module are disposed on the first circuit structure in a misalignment arrangement, and the first electronic element is adjacent to the optical engine module.

19. The method of claim 11, wherein the second electronic element and the optical engine module are disposed on the first circuit structure in a misalignment arrangement, and a spacing between the second electronic element and the optical engine module is less than 1400 microns.

20. The method of claim 11, further comprising disposing a stepped heat dissipating member having a first step portion and a second step portion on the carrier structure, wherein the second step portion of the stepped heat dissipating member is higher than the first step portion, the first step portion of the stepped heat dissipating member is in contact with the first electronic element and the second electronic element, and the second step portion of the stepped heat dissipating member is in contact with the optical engine module.
